(19) United States
(12) Patent Application Publication
(10) Pub. No.: US 2008/0150128 A1
(43) Pub. Date: Jun. 26, 2008

(54) Heat dissipating chip structure and fabrication method thereof and package having the same

(75) Inventors: Liang-Yi Hung, Taichung (TW); Yu-Po Wang, Taichung Hsien (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/004,779

(22) Filed: Dec. 21, 2007

(30) Foreign Application Priority Data
Dec. 25, 2006 (CN) 095148692

(51) Int. Cl. H01L 23/34; H01L 21/02

(52) U.S. Cl. 257/713; 438/113; 438/122; 257/E23.101; 257/E21.002

(57) ABSTRACT

A heat dissipating chip structure and a fabrication method thereof and a package having the same are provided. The fabrication method mainly includes: forming a metal layer on an non-active surface of a wafer having a plurality of chips with the metal layer thereof providing a better solder bonding with a thermal interface material at positions corresponding to centers of each chips, and not being disposed on the cutting paths between the chips to prevent crack and peel off during the cutting. Further, when the chips are subsequently mounted on a chip carrier and further attached to a heat dissipating sheet with another metal layer on a surface thereof with the thermal interface material (TIM), with different surface areas of the metal layers formed on the heat dissipating sheet and the chip, an inward and downward force is generated in the TIM to limit an wetting area.

### BACKGROUND OF THE INVENTION

1. Field of the Invention

This invention generally relates to a semiconductor chip and a fabrication method thereof and a package having the same, and more specifically, to a heat dissipating chip structure and a fabrication method thereof and a package having the same.

2. Description of Related Art

Flip chip ball grid array (FCBGA) semiconductor package is a package structure that has flip chips and a ball grid array, where the active surfaces of at least a semiconductor chip are electrically connected to a surface of a substrate via a plurality of conductive bumps, and a plurality of solder balls are disposed on the other surface of the substrate for serving as input/output terminals. Such package structure substantially minimizing the package size thereof, and eliminating the conventional wire design, thereby reducing impedance and enhancing electrical performance to avoid signal failing during the transmission process. Therefore, the FCBGA semiconductor package has become the main stream of the next generation of packaging technology for the chips and the electronic elements.

With the advantageous features, mostly, the FCBGA package is applied to the electronic elements with high integration meeting the requirements of such electronic elements. However, operation heat generated from such electronic elements is much higher than that generated from the general packages since such electronic elements are operated in high frequency. Therefore, heat dissipation efficiency has become critical for the quality and yield of such packaging.

In the known FCGBA semiconductor package, a heat dissipating sheet directly bonded to the non-active surface thereof is used for heat dissipating, i.e, heat generated therein does not need to be dissipated via an encapsulant filled between the non-active surface and heat dissipating sheet with low heat conductivity, thereby a better heat dissipation efficiency is achieved.

Generally, the bonding material that is used for bonding the heat dissipating sheet to the non-active surface of the flip chip semiconductor chip is epoxy-based material with the heat conductivity coefficient thereof being about 2˜4 w/m ° K. Since the heat conductivity coefficient of the heat dissipating sheet, which are generally hundreds w/m ° K (the heat conductivity coefficient of copper is 400 w/m ° K), is relatively much higher than that of the epoxy-based material, it appears that the heat dissipation is not desirably efficient. Therefore, as the higher the heat dissipating efficiency is required by the electronic products or the semiconductor package elements, a higher heat conductivity coefficient bonding material is needed in the known FCGBA semiconductor package for providing an efficient heat dissipation between the heating dissipating sheet and the flip chip semiconductor chip.

In view of the aforementioned reasons, U.S. Pat. Nos. 6,504,242, 6,380,621, and 6,504,723 use a tin-based (Sn-based) solder material as a thermal interface material (TIM) that bonds the heat dissipating sheet and the flip chip semiconductor chip. Since such solder material has metal component, the heat conductivity coefficient thereof is about 50 w/m ° K. If such solder material is made of pure tin, the heat conductivity coefficient thereof can be up to 86 w/m ° K. Therefore, in comparison with the conventional epoxy-based bonding material, such tin-based (Sn-based) solder material with a much higher heat conductivity and is more suitable for heat dissipating.

However such tin-based (Sn-based) solder material still have some problems. Please refer to FIG. 1, the thermal interface material made of a solder material 15 is used for bonding a heat dissipating sheet 13, which is generally made of copper, and a flip chip semiconductor chip 12. Since the solder material 15 has great wetting capability with the heat dissipating sheet 13, the solder material 15 will diffuse quickly on the heat dissipating sheet 13 as soon as the fusion process starts. Thus the thickness formed between the heat dissipating sheet 13 and the flip chip semiconductor chip 12 is not sufficient to form a solder bonding, and the bonding area between the solder material 15 and the flip chip semiconductor chip 12 is also reduced, thus causes breakage of solder material therebetween and affects heat dissipating efficiency and product reliability.

Please refer to FIG. 2, which is a sectional view of diagram for a flip chip semiconductor chip according to the U.S. Pat. No. 6,380,621. As shown, metal layers 24 made of, for example nickel (Ni) or gold (Au), are preformed on a surface of a heat dissipating sheet 23 and a non-active surface of a flip chip semiconductor chip 22, for allowing a solder material 25 to form a solder bonding with the metal layers 24 in a subsequent fusion process, if a thermal interface material, such as the solder material 25 is used, and thus limiting the wetting area.

Such technique requires to pre-form metal layers of nickel (Ni) or gold (Au) on one surface of the heat dissipating sheet and the non-active surface of the flip chip semiconductor chip individually in the fabrication process with the steps of: forming a nickel or gold metal layer on the back (non-active) surface of a wafer that has a plurality of chips, cutting the wafer along the cutting paths between the chips to produce a plurality of chips with each of the chips having nickel or gold coated on the non-active surface thereof. However, the metal coating material is easily to get crack or peel off in the cutting process, thereby affecting the quality of the solder bonding formed subsequently with solder material.

Please refer to FIGS. 3A and 3B, which are sectional views showing a flip chip semiconductor chip disclosed by U.S. Pat. No. 6,504,723. A heat dissipating structure 33 is provided, and the heat dissipating structure 33 includes: a raised section 331 that protrudes downward from the center of the heat dissipating structure 33 and then shrinks gradually, and an extension section 332 that extends downward from each side of the heat dissipating structure 33. The center raised section 331 has a flat bottom and four sloping surfaces, the surfaces of the raised section 331 has been preapplied with soldering flux 36, and then the heat dissipating structure 33 is pressed down via a bonding material 37 and then bonds to a substrate 31 that has a flip chip semiconductor chip 32 mounted on atop. The raised section 331 of the heat dissipating structure 33 is pressed to the solder material 35 that is preapplied on the non-active surface of the flip chip semiconductor chip 32, and the fusion process is performed on the solder material 35, such that the solder material 35 disperses in the gap between the raised section 331 of the heat dissipating structure 33 and the flip chip semiconductor chip 32, and the solder material 35 is held by the sloping surfaces of the raised section 331 so as to restrict the flow thereof.

However, such heat dissipating structure is too complicated and also has high production cost, it does not answer to the practical application and the economic consideration.

Hence, it is a highly urgent issue in the industry for how to provide a technique that has simple application and low production cost and is capable of restricting the solder thermal interface material to the wetting area between the heat dissipating sheet and the semiconductor chip in order to prevent it from improper overflowing, meanwhile the technique is also capable of avoiding using a complicated heat dissipating structure without the need of preapplying metal layers on the heat dissipating sheet and the semiconductor chip, thereby giving the benefits of saving fabrication time and production cost.

### SUMMARY OF THE INVENTION

In view of the aforementioned disadvantages of the prior art, it is a primary objective of the present invention to provide a heat dissipating chip structure and a fabrication method thereof and a package having the heat dissipating chip structure, which are capable of restricting the thermal interface material to a wetting area between a heat dissipating sheet and a semiconductor chip.

It is another objective of the present invention to provide a heat dissipating chip structure and a fabrication method thereof and a package having the heat dissipating chip structure, which are free from cracking and peeling off of metal coating materials on non-active surfaces of wafers in the cutting process, where those problems further affects the quality of a solder bonding, which is subsequently formed by mounting the heat dissipating sheet on the semiconductor chip with solder thermal interface materials in between.

It is a further objective of the present invention to provide a heat dissipating chip structure and a fabrication method thereof and a package having the heat dissipating chip structure, which are free from using a complicated heat dissipating structure, thereby saving fabrication time and production cost.

To achieve the aforementioned and other objectives, a heat dissipating chip structure is provided according to the present invention. The heat dissipating chip structure comprises: a chip having an active surface and a non-active surface opposing thereto; and a metal layer formed on the non-active surface with margins thereof being in a distance from that of the chip.

By this way, the chip is ready to be attached onto a chip carrier, and a heat dissipating sheet is allowed to be attached to the non-active surface of the chip with a thermal interface material mounted therebetween for dissipating heat generated from chip while it is operating. Since the metal layer provided in the present invention is formed on the non-active surface of the wafer having a plurality of chips at the positions only corresponding to a center of each chip and are capable of providing a better solder bounding with a thermal interface material, i.e. the metal layer is not formed on the cutting paths between the chips, the present invention prevents the metal layer from cracking and peeling off while cutting the wafer along the cutting paths between the chips.

The present invention also discloses a fabrication method of a heat dissipating chip structure, which comprises: providing a wafer having a plurality of chips with the wafer and the chips each having an active surface and a non-active surface opposing thereto for forming a conductive layer on the non-active surface of the wafer; forming a metal layer on the conductive layer by means of, for example either electroplating or sputtering; forming a resist layer on the metal layer with an indentation formed in a grid pattern for exposing a first portion of the metal layer mounted on margins of each of the chips; removing the first portion of metal layer and a portion of the conductive layer therebeneath; removing the resist layer; and cutting the wafer to form a plurality of chips with each of the chips having a second portion of the metal layer on the non-active surface thereof, and respective margins thereof is in a distance from that of the second portion of the metal layer.

The present invention also discloses a fabrication method of a heat dissipating chip structure of another preferred embodiment, which comprises: providing a wafer having a plurality of chips with the wafer and the chips each having an active surface and a non-active surface opposing thereto for forming a conductive layer on the non-active surface of the wafer; forming a resist layer on the conductive layer and a plurality of indentations in the resist layer for exposing a portion of the conductive layer mounted on centers of each of the chips to form the resist layer in a grid pattern; performing an electroplating process to depositing a metal layer in each of the indentations; removing the resist layer in a grid pattern and a portion of the conductive layer thereunder; and cutting the wafer to form a plurality of chips with each of the chips having the metal layer on the non-active surface thereof, and respective margins thereof is in a distance from that of the metal layer.

The present invention further discloses a heat dissipating chip package, which comprises: a chip carrier; a chip having an active surface and a non-active surface opposing thereto and mounted on the chip carrier by the active surface thereof; a metal layer formed on the non-active surface of the chip with margins thereof being in a distance from that of the chip; and a heat dissipating sheet having a metal layer formed on a surface thereof mounted on the non-active surface of the chip by the surface with the metal layer formed thereon via a thermal interface material (TIM), wherein a surface area of the metal layer formed on the heat dissipating sheet is greater than that of the metal layer formed on the chip for generating an inward and downward slanting pull force in the thermal interface material which further limits an wetting area of the thermal interface material.

The heat dissipating sheet is made of such as copper material, the thermal interface material is, for example a solder material, the metal layers can be, for example nickel or gold, and the metal layers can be made of the same or different material.

In view of the aforementioned description, the heat dissipating chip structure and the fabrication method thereof and the package having the same according to the present invention mainly, on the non-active surface of the wafer that has a plurality of chips, forms a metal layer that is capable of providing a better solder bonding with a thermal interface material at positions corresponding to centers of the chips. Namely, the metal layer is not formed in the cutting paths, which is lain between the chips for preventing cutting across the metal layer, thus further preventing the metal layer from cracking and peeling off. In addition, with the chip being mounted on the chip carrier by the active surface thereof, and being further attached to the heat dissipating sheet having a metal layer formed on the non-active surface thereof with the thermal interface material mounted therebetween, and with the surface area of the metal layer formed on the heat dissipating sheet is greater than that of the metal layer formed on the chip, the solder bonding area formed between the thermal interface material and the metal layer on the heat dissipating sheet side is greater than on the chip side, thus the inward and downward slanting pull force is generated to limit the wetting area of the thermal interface material and further the diffusion of the thermal interface material is prevented. Hence, the present invention does not need to use a complicated heat dissipating structure as disclosed in the prior art, thereby saving fabrication time and production cost.

### BRIEF DESCRIPTION OF DRAWINGS

The present invention can be more fully understood by reading the following detailed description of the preferred embodiments, with reference made to the accompanying drawings, wherein:

FIG. 1 is a schematic view showing the wetting diffusion of a solder thermal interface material that is used to bond a heat dissipating sheet to a flip chip semiconductor chip according to the prior art;

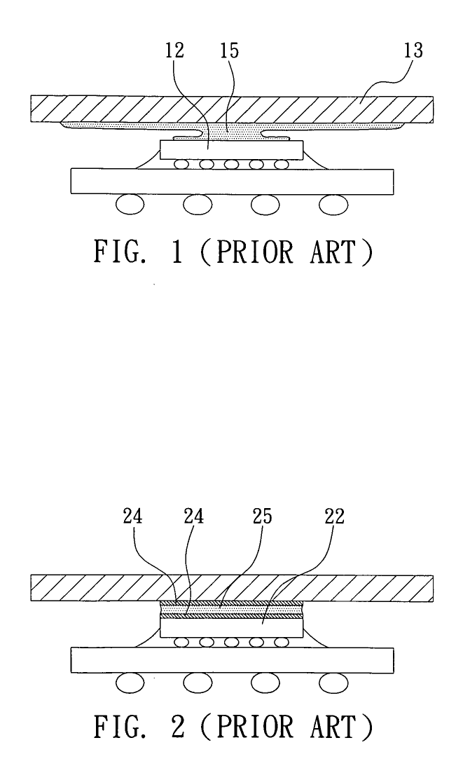

FIG. 2 is a sectional view showing of a flip chip semiconductor package disclosed by U.S. Pat. No. 6,380,621;

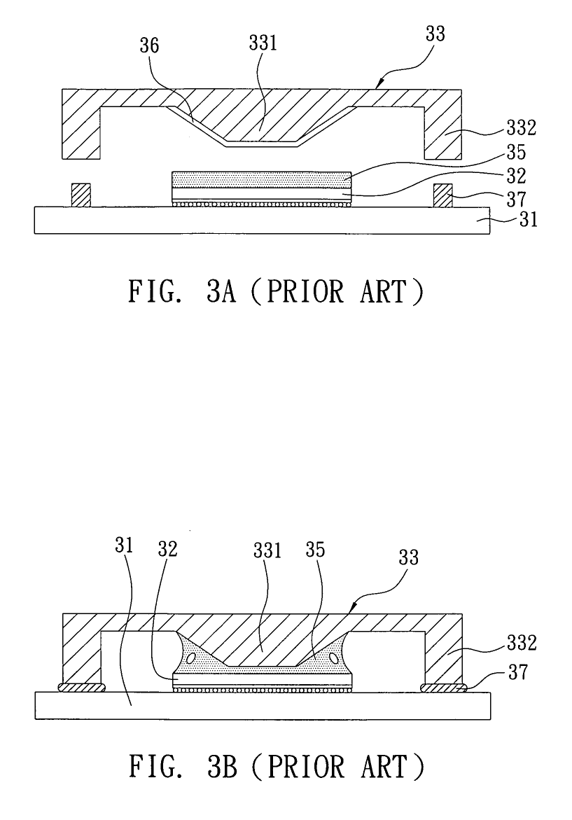

FIGS. 3A and 3B are schematic views showing a flip chip semiconductor package disclosed by U.S. Pat. No. 6,504,723;

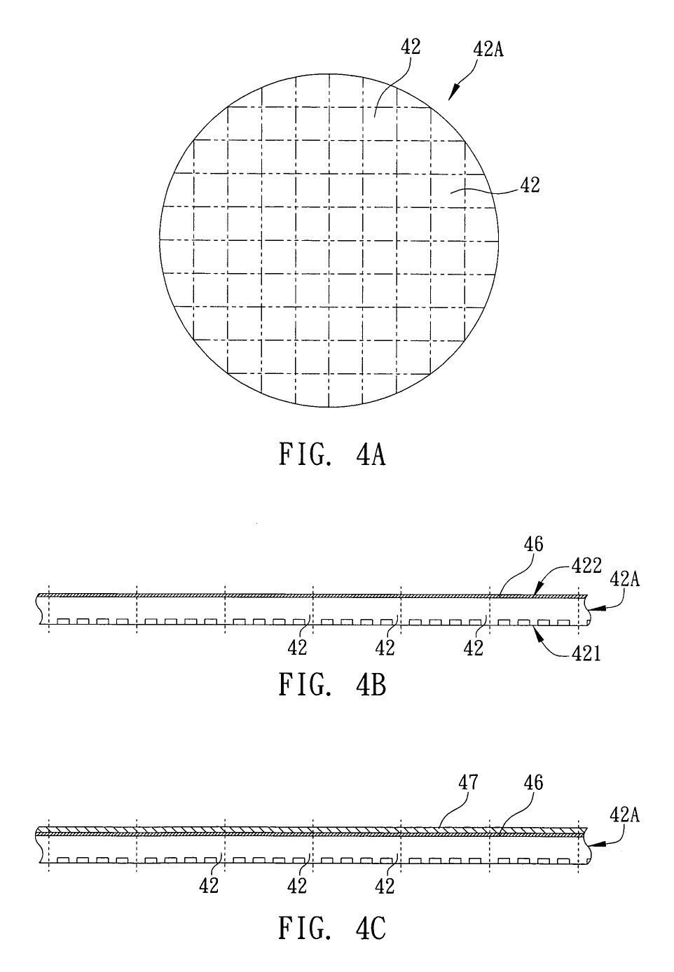

FIGS. 4A to 4F are schematic views showing a heat dissipating chip structure and a fabrication method thereof according to a first preferred embodiment of the present invention;

FIGS. 5A to 5D are schematic views showing a heat dissipating chip structure and a fabrication method thereof according to a second preferred embodiment of the present invention; and

FIG. 6 is a schematic view showing a heat dissipating chip package according to an embodiment of the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

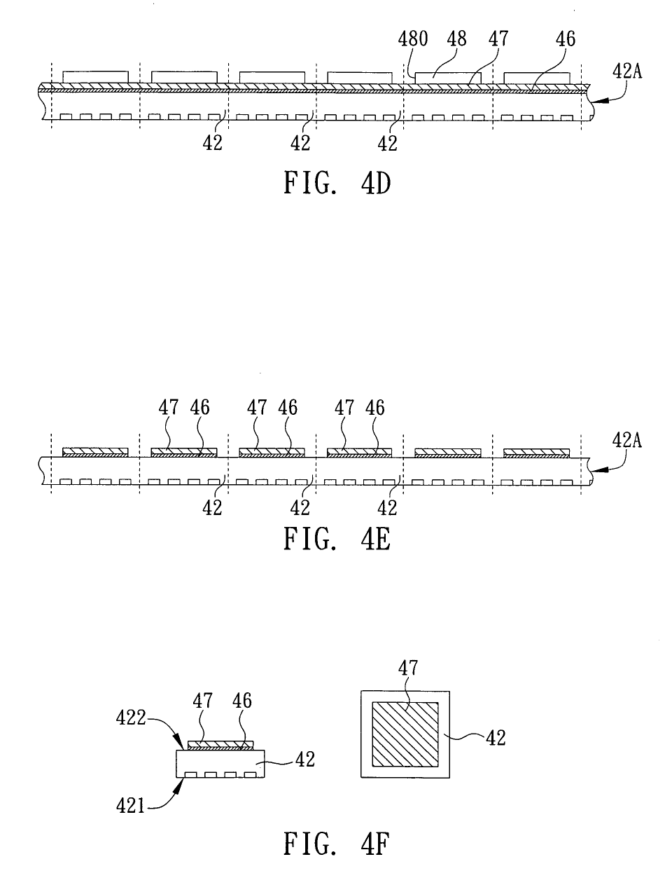

Please refer to FIGS. 4A to 4F, which are schematic views showing a heat dissipating chip structure and a fabrication method thereof according to a first embodiment of the present invention.

As shown in FIGS. 4A and 4B, a wafer 42A that has a plurality of chips 42 is provided, wherein the chips 42 and wafer 42A each has an active surface 421 and a non-active surface 422 opposing to the active surface 421. A conductive layer 46, for example a thin copper layer, is formed on the non-active surface 422 by means of physical or chemical deposition.

As shown in FIG. 4C, a metal layer 47 is formed on the conductive layer 46 by means of electroplating or sputtering coating process, where the metal layer 47 is made of, for example nickel, gold, or others.

As shown in FIG. 4D, a resist layer 48 is formed on the metal layer 47, where the resist layer 48 can be a photo-sensitive material, and an indentation 480 in a grid pattern is also formed on the resist layer 48 to expose a first portion of the metal layer 47, which is mounted on margins of each of the chips 42.

As shown in FIG. 4E, the first portion of the metal layer 47 exposed from the indentation 480 of the resist layer 48 and the a portion of the conductive layer 46 under the first portion of the metal layer 47 are removed by means of such as etching, and then the resist layer 48 is removed.

As shown in FIG. 4F, simulation of the chips 42 by cutting the wafer 42A along the cutting paths lain between the chips 42 to form a plurality of chips 42 with each of the chips having a second portion of the metal layer 47 formed on the non-active surface 422, and there is a distance between margins of the second portion of the metal layer 47 and margins of the chips 42.

By the mentioned steps, the chips 42 are readily to be mounted onto a chip carrier and a heat dissipating sheet is able to be mounted on the non-active surface of the chip with a thermal interface material mounted therebetween for dissipating heat generated from the chip while it is operating. In the present invention, the metal layer is not formed on the cutting paths between the chips, the present invention prevents the metal layer from cracking and peeling off while cutting along the cutting paths between the chips.

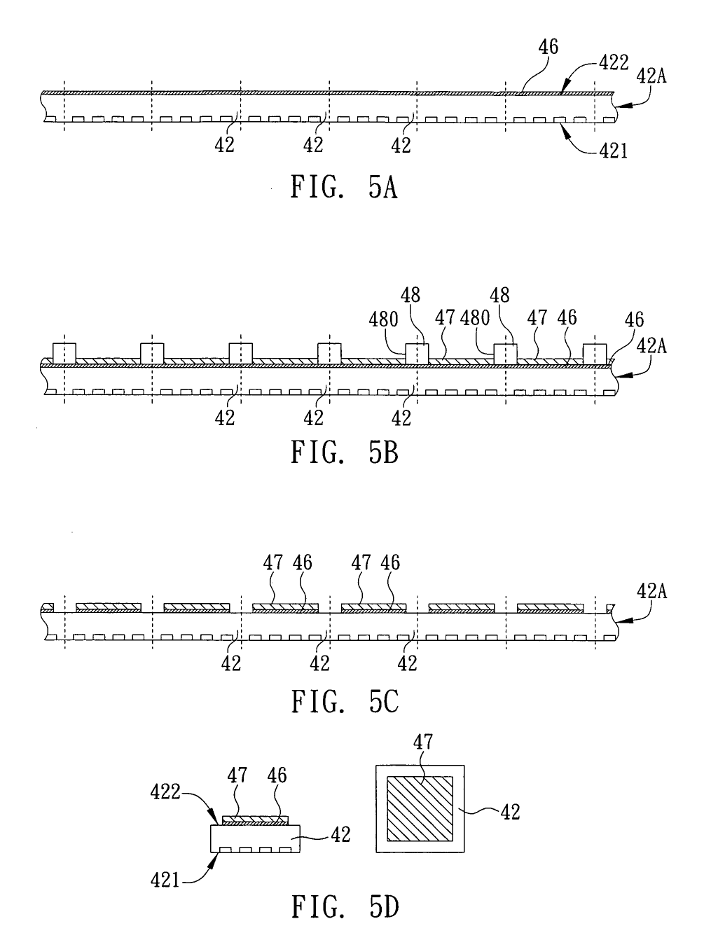

Please further refer to FIGS. 5A to 5D, which are schematic view showing a heat dissipating chip structure fabrication method according to a second embodiment of the present invention.

As shown in FIG. 5A, a wafer 42A that has a plurality of chips 42, and a conductive layer 46 are provided, where the chips 42 and the wafer 42A each has an active surface 421 and a non-active surface 422 opposing to the active surface 421, and the conductive layer 46 is formed on the non-active surface 422.

As shown in FIG. 5B, a resist layer 48 is formed on the conductive layer 46, and a plurality of indentation 480 are formed for exposing a portion of the conductive layer 46 on centers of each of the chips to form the resist layer 48 in a grid pattern. Then, an electroplating process is performed to form a metal layer 47 in each of the indentations 480 of the resist layer by means of electroplating deposition.

As shown in FIG. 5C, after the electroplating process, the resist layer 48 and a part of the conductive layer 46 under the resist layer 48 are removed by means of etching.

As shown in FIG. 5D, cutting the wafer 42A along the cutting paths between the chips 42 to form a plurality of chips 42 with each of the chips 42 having the metal layer 47 mounted thereon, where there is a distance between margins of the metal layer 47 and margins of each chips 42.

By means of aforementioned fabrication method, the present invention further discloses a heat dissipating chip structure, which comprises: a chip 42 having an active surface 421 and a non-active surface 422 opposing thereto; and a metal layer 47 formed on the non-active surface 422 with margins thereof being in a distance from that of the chip 42.

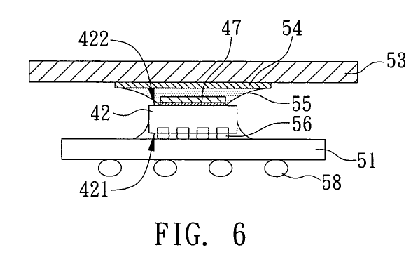

Please refer to FIG. 6, the present invention further discloses a heat dissipating chip package, which is produced from attaching and packing the chip structure fabricated from the above-mentioned methods on a chip carrier. The heat dissipating chip package comprises: a chip carrier 51; a chip 42, which has an active surface 421 and a corresponding non-active surface 422 and is mounted on the chip carrier 51 by the active surface 421; a metal layer 47 formed on the non-active surface 422 with margins thereof being in a distance from that of the chip 42; and a heat dissipating sheet 53 having a metal layer 54 formed on a surface thereof, wherein the heat dissipating sheet 53 is attached to the non-active surface 422 of the chip 42 by the surface with the metal layer 47 mounted thereon with a thermal interface material (TIM) 55 mounted therebetween, and a surface area of the metal layer 54 formed on the heat dissipating sheet 53 is larger than that of the metal layer 47 formed on the chip 42, thus an inward and downward slanting pull force is generated in the thermal interface material 55, which further limits an wetting area of the thermal interface material 55.

The chip carrier 51, for example is a ball grid array (BGA) substrate, which has an active surface and a non-active surface opposing thereto for allowing the chip 42 to be mounted and electrically connected to a first surface of the substrate 51 by the active surface 421 with a plurality of conductive bumps 56 mounted therebetween, and also for allowing a plurality of solder balls 58 to be mounted on a second surface of the substrate 51, which is used for electrically connecting the chip 42 with external devices. And of course, the chip carrier 51 can also be a lead frame.

The heat dissipating sheet 53 is made of metal, such as copper, and the metal layer 54, such as nickel or gold layer, is formed on the surface of the heat dissipating sheet 53. The area of the metal layer 54 formed on the heat dissipating sheet 53 is greater than that of the metal layer 47 formed on the non-active surface 422 of the chip 42, and the metal layer 54 and the metal layer 47 can be made of the same or different materials.

The heat dissipating sheet 53 is attached to the non-active surface 422 of the chip 42 by the surface thereof with the thermal interface material 55 in between, for example a solder material. In a fusion process, since the metal layer 54 and the metal layer 47 are respectively formed on the surfaces of the heat dissipating sheets 53 and the non-active surface 422 of the chip 42, the solder thermal interface material 55 will form the solder bonding with the metal layer 54 and the metal layer 47. In addition, since the surface area of the metal layer 54 formed on the heat dissipating sheet 53 is greater than that of the metal layer 47 formed on the non-active surface 422 of the chip 42, after the processes of fusion and wetting, the downward and inward slanting pull force will be generated from the thermal interface material 54 to further limit the wetting area.

In view of the foregoing descriptions, the heat dissipating chip structure and the fabrication method thereof and the package having the same according to the present invention mainly, on the non-active surface of the wafer that has a plurality of chips, forms a metal layer that is capable of providing a solder bonding with a thermal interface material at positions corresponding to centers of the chips. Namely, the metal layer is not formed in the cutting paths, which is lain between the chips for preventing cutting across the metal layer, thus further preventing the metal layer from cracking and peeling off. In addition, with the chip being mounted on the chip carrier by the active surface thereof, and being further attached to the heat dissipating sheet having a metal layer formed on the non-active surface thereof with the thermal interface material mounted therebetween, and with the surface area of the metal layer formed on the heat dissipating sheet is greater than that of the metal layer formed on the chip, the solder bonding area formed between the thermal interface material and the metal layer on the heat dissipating sheet side is greater than on the chip side, thus the inward and downward slanting pull force is generated to limit the wetting area of the thermal interface material and further the diffusion of the thermal interface material is prevented. Hence, the present invention does not need to use a complicated heat dissipating structure as disclosed in the prior art, thereby saving fabrication time and production cost.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should peel within the scope of the appended claims.

What is claimed is:

1. A fabrication method of a heat dissipating chip structure, comprising:
providing a wafer having a plurality of chips with the wafer and the chips each having an active surface and a non-active surface opposing thereto for forming a conductive layer on the non-active surface of the wafer;
forming a metal layer on the conductive layer;
forming a resist layer on the metal layer with an indentation formed in a grid pattern for exposing a first portion of the metal layer mounted on margins of each of the chips;
removing the first portion of metal layer and a portion of the conductive layer thereunder;
removing the resist layer; and
cutting the wafer to form a plurality of chips with each of the chips having a second portion of the metal layer on the non-active surface thereof, and respective margins thereof is in a distance from that of the second portion of the metal layer.

2. The fabrication method of claim 1, wherein the metal layer is formed on the conductive layer by one of an electroplating and a sputtering.

3. The fabrication method of claim 1, wherein the metal layer is made of one of nickel and gold.

4. The fabrication method of claim 1, wherein the conductive layer is a thin copper layer.

5. A fabrication method of a heat dissipating chip strcture, comprising:
providing a wafer having a plurality of chips with the wafer and the chips each having an active surface and a non-active surface opposing thereto for forming a conductive layer on the non-active surface of the wafer;
forming a resist layer on the conductive layer and a plurality of indentations in the resist layer for exposing a portion of the conductive layer mounted on centers of each of the chips to form the resist layer in a grid pattern;
depositing a metal layer in each of the indentations;
removing the resist layer in a grid pattern and a portion of the conductive layer thereunder; and
cutting the wafer to form a plurality of chips with each of the chips having the metal layer on the non-active surface thereof, and respective margins thereof being in a distance from that of the metal layer.

6. The fabrication method of claim 5, wherein the metal layer is made of one of nickel and gold.

7. The fabrication method of claim 5, wherein the conductive layer is a thin copper layer.

8. The fabrication method of claim 5, wherein the step of depositing a metal layer in each of the indentations is performed by an electroplating process.

9. A heat dissipating chip structure, comprising:
a chip having an active surface and a non-active surface opposing thereto; and
a metal layer formed on the non-active surface with margins thereof being in a distance from that of the chip.

10. The heat dissipating chip structure of claim 9, wherein the metal layer is made of one of nickel and gold.

11. The heat dissipating chip structure of claim 9, further comprising a conductive layer mounted between the chip and the metal layer.

12. The heat dissipating chip structure of claim 11, wherein the conductive layer is a thin copper layer.

13. A heat dissipating chip package, comprising:
a chip carrier;
a chip having an active surface and a non-active surface opposing thereto mounted on the chip carrier by the active surface thereof;
a metal layer formed on the non-active surface with margin thereof being a distance from that of the chip; and
a heat dissipating sheet having a metal layer formed on a surface thereof and attached to the non-active surface of the chip by the surface thereof with a thermal interface material (TIM) mounted therebetween.

14. The heat dissipating chip package of claim 13, wherein an area of the metal layer formed on the heat dissipating sheet is greater than that of the metal layer formed on the non-active surface of the chip.

15. The heat dissipating chip package of claim 13, wherein the chip carrier is one of a substrate and a lead frame.

16. The heat dissipating chip package of claim 13, wherein the chip is mounted on and electrically connected to the chip carrier by the active surface with a plurality of conductive bumps mounted therebetween.

17. The heat dissipating chip package of claim 13, wherein the heat dissipating sheet is made of copper, the thermal interface material is a solder material, each of the metal layers is made one of nickel and gold.

18. The heat dissipating chip package of claim 13, further comprising a solder bonding formed by the thermal interface material and the metal layers, wherein a surface area of the metal layer formed on the surface of the heat dissipating sheet is greater than that of the metal layer formed on the non-active surface of the chip to generate a downward and inward slanting pull force for limiting an wetting area of the thermal interface material.

19. The heat dissipating chip package of claim 13, further comprising a conductive layer between the non-active surface of the chip and the metal layer formed thereon.

20. The heat dissipating chip package of claim 19, wherein the conductive layer is a thin copper layer.
